(19) United States
(12) Patent Application Publication
(10) Pub. No.: US 2026/0008668 A1
(43) Pub. Date: Jan. 8, 2026

(54) CAPACITIVE SENSOR AND METHOD FOR MANUFACTURING SAME

(71) Applicant: Murata Manufacturing Co., Ltd., Nagaokakyo-shi (JP)

(72) Inventors: Masakazu FUKUMITSU, Nagaokakyo-shi (JP); Tadayuki OKAWA, Nagaokakyo-shi (JP)

(21) Appl. No.: 19/325,906

(22) Filed: Sep. 11, 2025

Related U.S. Application Data
(63) Continuation of application No. PCT/JP2024/012175, filed on Mar. 27, 2024.

(51) Int. Cl. B81B 3/00; B81C 1/00; G01D 5/241

(52) U.S. Cl. CPC B81B 3/001; B81C 1/00968; G01D 5/241; B81B 2201/0235; B81B 2201/0242; B81B 2201/0264; B81B 2203/0127; B81B 2203/019; B81C 2201/0178; B81C 2203/0109

(57) ABSTRACT

A capacitive sensor that includes: a first substrate layer; and a device layer having a movable portion. The movable portion has a first main surface facing the first substrate layer and at least one first protrusion on the first main surface. The first protrusion has a first top portion having a curved surface in a central area of the first protrusion in a plan view of the device layer, and a first slope around the first top portion. The capacitive sensor is configured to detect a change in electrostatic capacity based on a distance between the first substrate layer and the movable portion.

### CROSS REFERENCE TO RELATED APPLICATIONS

The present application is a continuation of International application No. PCT/JP2024/012175, filed Mar. 27, 2024, which claims priority to Japanese Patent Application No. 2023-085954, filed May 25, 2023, the entire contents of each of which are incorporated herein by reference.

### TECHNICAL FIELD

The present disclosure relates to a capacitive sensor and a method for manufacturing the capacitive sensor.

### BACKGROUND ART

Capacitive sensors detect inertia, pressure, and other parameters based on changes in electrostatic capacity corresponding to changes in the gap between a substrate layer and a device layer. For example, the substrate layer has electrodes, and the device layer has a movable portion, a support portion that movably supports the movable portion, and a spring portion that elastically connects the movable portion and the support portion to each other. Capacitive sensors are manufactured, for example, by MEMS (Micro Electro Mechanical Systems) technology.

For example, Patent Document 1 discloses an inertial sensor including a substrate, a movable body capable of oscillating, a support beam that supports the movable body, and a protrusion on the movable body or the surface facing the movable body, wherein a rounded portion is provided on the contact surface of the protrusion.
Patent Document 1: Japanese Unexamined Patent Application Publication No. 2022-22024

### SUMMARY OF THE DISCLOSURE

In the inertial sensor described in Patent Document 1, the protrusion and the rounded portion reduce the occurrence of so-called sticking, an operational defect in which the movable body adheres to the contact surface. However, if the movable body is significantly displaced due to an impact, such as a drop, the inertial sensor may be damaged by a collision between the movable body and the protrusion.

The present disclosure has been made in view of the above circumstances, and the present disclosure is directed to a capacitive sensor having improved reliability and a method for manufacturing the capacitive sensor.

A capacitive sensor according to one aspect of the present disclosure includes: a first substrate layer; and a device layer having a movable portion, wherein the movable portion has a first main surface facing the first substrate layer and at least one first protrusion on the first main surface, the first protrusion has a first top portion having a curved surface in a central area of the first protrusion in plan view, and a first slope around the first top portion, and the capacitive sensor is configured to detect a change in electrostatic capacity based on a distance between the first substrate layer and the movable portion.

A method for manufacturing a capacitive sensor according to another aspect of the present disclosure includes: disposing a first mask on a surface of a base; thermally oxidizing the base through openings in the first mask to form thermally oxidized regions and connecting the thermally oxidized regions expanding from the openings to each other under the first mask; removing the thermally oxidized regions from the base so as to form a protrusion at a position where the thermally oxidized regions are connected to each other; and forming a movable portion by subjecting the base to removal processing.

According to the present disclosure, a capacitive sensor having improved reliability and a method for manufacturing the capacitive sensor can be provided.

### BRIEF DESCRIPTION OF THE DRAWINGS

FIG. 1 is a cross-sectional view of a capacitive sensor according to a first embodiment.

FIG. 2 is an enlarged cross-sectional view of a device layer.

FIG. 3 is a cross-sectional image of a protrusion.

FIG. 4 is a perspective image of an example of the protrusion.

FIG. 5 is a perspective image of an example of the protrusion.

FIG. 6 is a flow chart of a method for manufacturing the capacitive sensor according to the embodiment.

FIG. 7 is a cross-sectional view illustrating the process for manufacturing the capacitive sensor.

FIG. 8 is a cross-sectional view illustrating the process for manufacturing the capacitive sensor.

FIG. 9 is a cross-sectional view illustrating the process for manufacturing the capacitive sensor.

FIG. 10 is a cross-sectional view illustrating the process for manufacturing the capacitive sensor.

FIG. 11 is a cross-sectional view illustrating the process for manufacturing the capacitive sensor.

FIG. 12 is a cross-sectional view of a capacitive sensor according to a second embodiment.

### DESCRIPTION OF THE PREFERRED EMBODIMENTS

Embodiments of the present disclosure will be described below with reference to the drawings. The drawings of this embodiment are illustrative, and the dimensions and shape of each part are schematic. Therefore, the technical scope of the present disclosure should not be construed as being limited to the embodiments.

### First Embodiment

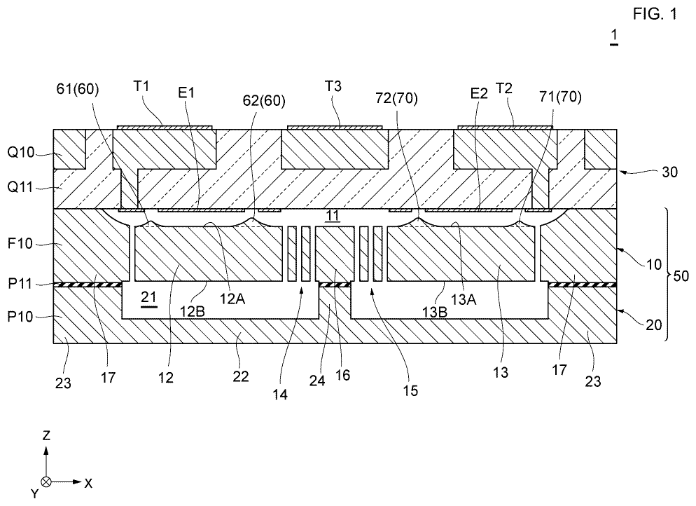

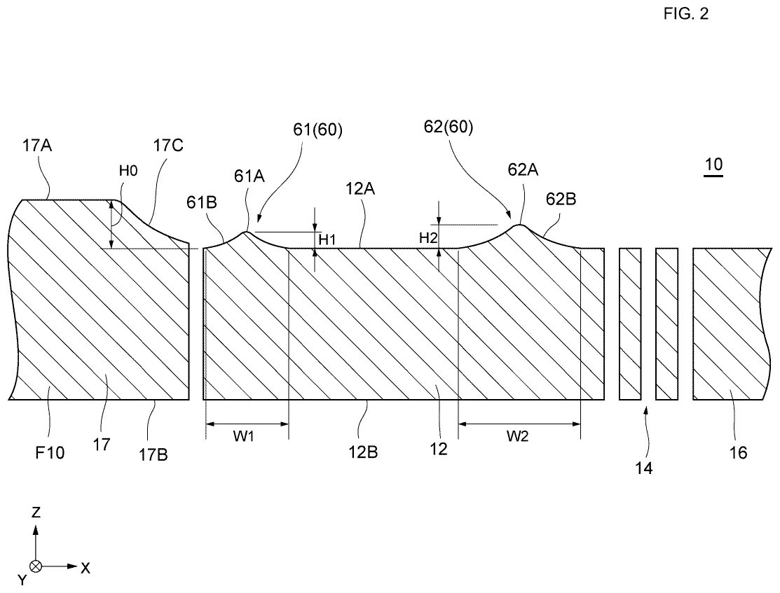

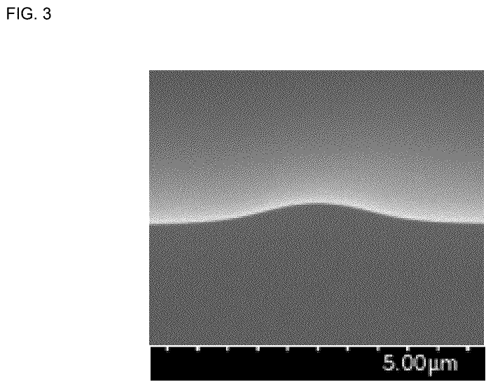

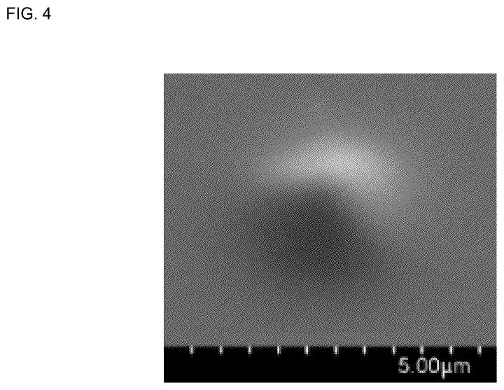

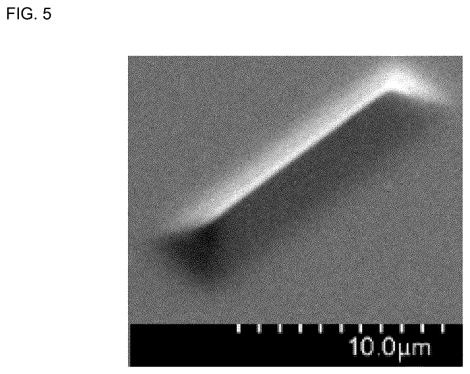

First, the structure of a capacitive sensor 1 according to a first embodiment of the present disclosure will be described with reference to FIGS. 1 to 5. FIG. 1 is a cross-sectional view of the capacitive sensor according to the first embodiment. FIG. 2 is an enlarged cross-sectional view of a device layer. FIG. 3 is a cross-sectional image of a protrusion. FIGS. 4 and 5 are perspective images of examples of the protrusion.

Each component of the capacitive sensor 1 will be described below. For convenience, each figure may be provided with a Cartesian coordinate system consisting of an X-axis, a Y-axis, and a Z-axis to clarify the mutual relationship among the figures and to facilitate understanding of the positional relationships between the components. The directions parallel to the X-axis, the Y-axis, and the Z-axis are the X-axis direction, the Y-axis direction, and the Z-axis direction, respectively. The plane defined by the X-axis and the Y-axis is the XY plane. For convenience, the positive side of the Z-axis (the direction of the arrow) is referred to as up or upper, and the negative side of the Z-axis (the direction opposite to the arrow) is referred to as down or lower. However, the orientation of the capacitive sensor 1 is not limited to this.

The capacitive sensor 1 includes a device layer 10, a lower cover 20, and a upper cover 30. The lower cover 20, the device layer 10, and the upper cover 30 are stacked in this order in the Z-axis direction. Hereinafter, the Z-axis direction in which the lower cover 20, the device layer 10, and the upper cover 30 are stacked is referred to as the “thickness direction”. The device layer 10 and the lower cover 20 are bonded together to form an MEMS substrate 50. The upper cover 30 is bonded to the device layer 10 of the MEMS substrate 50. In other words, the upper cover 30 is bonded to the lower cover 20 with the device layer 10 interposed therebetween. The lower cover 20 and the upper cover 30 face each other with the device layer 10 interposed therebetween in the thickness direction. The lower cover 20 and the upper cover 30 constitute a package structure that forms, inside, a vibration space in which the device layer 10 vibrates. The upper cover 30 corresponds to an example of a first substrate layer, and the lower cover 20 corresponds to an example of a second substrate layer.

The device layer 10 is formed by a silicon substrate F10. The silicon substrate F10 corresponds to an example of a base of the device layer 10. The silicon substrate F10 is composed of single-crystal silicon. The silicon substrate F10 is composed of, for example, a p-type silicon (Si) semiconductor. The silicon substrate F10 can contain boron (B) or another element as a p-type dopant. The silicon (Si) used for the silicon substrate F10 has, for example, a resistance of about 10 mΩ·cm. The base of the device layer 10 is not limited to a silicon semiconductor as long as it is any material that can be thermally oxidized.

The device layer 10 includes movable portions 12 and 13, spring portions 14 and 15, a support portion 16, and a peripheral portion 17. The device layer 10 forms a movable space 11 between the device layer 10 and the upper cover 30. The movable space 11 defines the movable range of the movable portion 12 and 13 toward the upper cover 30 and is a gap located between the upper cover 30 and the movable portions 12 and 13 in the Z-axis direction and surrounded by the peripheral portion 17 in the XY plane direction. The movable portions 12 and 13, the spring portions 14 and 15, the support portion 16, and the peripheral portion 17 are formed by patterning the silicon substrate F10 through removal processing. The removal processing is performed, for example, by dry etching called DRIE (Deep Reactive Ion Etch). The removal processing may be performed by other techniques, such as wet etching and laser etching.

The movable portions 12 and 13 are configured such that a change in electrostatic capacity is detected based on the distance between the upper cover 30 and the movable portions 12 and 13. The movable portions 12 and 13 correspond to electrodes. The movable portion 12 forms an electrostatic capacity with an electrode E1 described below of the upper cover 30, and the movable portion 13 forms an electrostatic capacity with an electrode E2 described below of the upper cover 30. The movable portions 12 and 13 are held so as to be movable up and down and are held so that the movable portions 12 and 13 can move toward or away from the electrodes E1 and E2 of the upper cover 30. When the capacitive sensor 1 experiences inertial force (e.g., acceleration or angular velocity) or pressure in the Z-axis direction, the distance in the Z-axis direction between the upper cover 30 and the movable portions 12 and 13, that is, a gap in the movable space 11, changes, and the electrostatic capacity formed by the upper cover 30 and the movable portion 12 and 13 changes accordingly. By detecting this change in electrostatic capacity, the capacitive sensor 1 detects inertial force or pressure.

The movable portion 12 and the movable portion 13 are held by the spring portions 14 and 15 with the support portion 16 interposed therebetween and are configured to be movable up and down. Although not shown in the figures, the movable portion 12 and the movable portion 13 may be connected to each other without the spring portions 14 and 15 in the XY plane. In this case, for example, when the capacitive sensor 1 experiences a clockwise rotational force about the Y-axis as viewed from the negative side of the Y-axis, the gap between the electrode E1 and a upper surface 12A of the movable portion 12 becomes smaller, and the gap between the electrode E2 and a upper surface 13A of the movable portion 13 becomes larger. When the capacitive sensor 1 experiences a counterclockwise rotational force, the gap between the electrode E1 and the upper surface 12A of the movable portion 12 becomes larger, and the gap between the electrode E2 and the upper surface 13A of the movable portion 13 becomes smaller. The changes in electrostatic capacity resulting from these gap changes allow for detection of the rotational force.

The movable portion 12 has the upper surface 12A and a lower surface 12B, and the movable portion 13 has the upper surface 13A and a lower surface 13B. The upper surfaces 12A and 13A correspond to the first main surfaces of the movable portions 12 and 13 and face the upper cover 30. The lower surfaces 12B and 13B correspond to the second main surfaces of the movable portions 12 and 13 and face the lower cover 20.

A plurality of protrusions 60 are formed on the upper surface 12A of the movable portion 12. The protrusions 60 correspond to examples of first protrusions of the movable portion 12. The plurality of protrusions 60 include a protrusion 61 and a protrusion 62, which are different in height from each other. The protrusion 61 corresponds to an example of a low-height protrusion, and the protrusion 62 corresponds to an example of a high-height protrusion having a larger dimension in the Z-axis direction than the protrusion 61. The protrusion 62 is closer to the support portion 16 than the protrusion 61.

Referring to FIG. 2, the protrusion 61 has a height H1 in the Z-axis direction and a width W1 in the X-axis direction. The protrusion 62 has a height H2 in the Z-axis direction and a width W2 in the X-axis direction. The height H1 is the maximum distance in the Z-axis direction from the upper surface 12A to a top portion 61A. The height H2 is the maximum distance in the Z-axis direction from the upper surface 12A to a top portion 62A. The width W1 is the maximum distance in the X-axis direction between a slope 61B on the positive side of the X-axis from the top portion 61A described below and a slope 61B on the negative side of the X-axis from the top portion 61A described below. The width W2 is the maximum distance in the X-axis direction between a slope 62B on the positive side of the X-axis from the top portion 62A described below and a slope 62B on the negative side of the X-axis from the top portion 62A described below.

With respect to the dimensions of the protrusions 61 and 62, the relationship H1<H2 holds, and the relationship W1<W2 holds. For example, the relationship W1/H1=W2/H2 may hold. The ratio W1/H1 of the width W1 to the height H1 is sufficiently larger than 1. For example, the relationship 2≤W1/H1≤30 preferably holds, and the relationship 5≤W1/H1≤15 more preferably holds. Similarly, the ratio W2/H2 of the width W2 to the height H2 is sufficiently larger than 1. For example, the relationship 2≤W2/H2≤30 preferably holds, and the relationship 5≤W2/H2≤15 more preferably holds.

W1/2 corresponds to the dimension of the slope 61B in the X-axis direction described below, and H1 corresponds to the dimension of the slope 61B in the Z-axis direction. W2/2 corresponds to the dimension of the slope 62B in the X-axis direction described below, and H2 corresponds to the dimension of the slope 62B in the Z-axis direction. Since the dimension of the slope 61B in the Z-axis direction is smaller than that of the slope 61B in the X-axis direction, the relationship 1<(W1/2)/H1 holds. Similarly, the relationship 1<(W2/2)/H2 holds. For example, the relationship (W1/2)/H1=(W2/2)/H2 may hold. The relationship 2≤(W1/2)/H1 preferably holds, and the relationship 4≤(W1/2)/H1 more preferably holds. Similarly, the relationship 2≤(W2/2)/H2 preferably holds, and the relationship 4≤(W2/2)/H2 more preferably holds. In order for the protrusion 61 to fully demonstrate its function of preventing sticking between the movable portion 12 and the upper cover 30, the relationship (W1/2)/H1≤20 preferably holds, the relationship (W1/2)/H1≤10 more preferably holds, and the relationship (W1/2)/H1≤7.5 even more preferably holds. Similarly, the relationship (W2/2)/H2≤20 preferably holds, the relationship (W2/2)/H2≤10 more preferably holds, and the relationship (W2/2)/H2≤7.5 even more preferably holds.

Referring to FIGS. 2 and 3, the protrusion 61 has the top portion 61A having a curved surface in a central area of the protrusion 61 in plan view, and the slope 61B around the top portion 61A. The top portion 61A forms an upwardly convex shape. The slope 61B is a plane different from the crystal plane of the silicon substrate F10. The slope 61B has a curved surface and forms, for example, a downwardly convex shape in a region close to the upper surface 12A and an upwardly convex shape in a region close to the top portion 61A. The surface including the slope 61B from the upper surface 12A to the top portion 61A is formed as a smooth curved surface with a continuously changing gradient. The maximum angle of inclination of the slope 61B with respect to the upper surface 12A is, for example, 5 degrees to 45 degrees, preferably 5 degrees to 30 degrees, more preferably 10 degrees to 20 degrees. The maximum angle of inclination of the slope 61B is, for example, the angle of inclination of the slope 61B with respect to the upper surface 12A at the midpoint between the upper surface 12A and the top portion 61A in the Z-axis direction. In other words, the maximum angle of inclination of the slope 61B with respect to the upper surface 12A is the angle of inclination of the slope 61B with respect to the upper surface 12A at a height of H1/2 from the upper surface 12A. The dimension of the slope 61B in the Y-axis direction along the upper surface 12A is larger than the dimension of the slope 61B in the Z-axis direction intersecting the upper surface 12A.

The protrusion 62 has the top portion 62A having a curved surface in a central area of the protrusion 62 in plan view, and the slope 62B around the top portion 62A. The top portion 62A has the same shape as the top portion 61A, and the slope 62B has the same shape as the slope 61B. For example, the protrusion 62 and the protrusion 61 are geometrically similar, having the same shape but different sizes. In this case, the maximum angle of inclination of the slope 62B with respect to the upper surface 12A is substantially the same as the maximum angle of inclination of the slope 61B with respect to the upper surface 12A. The maximum angle of inclination of the slope 61B with respect to the upper surface 12A may differ from the maximum angle of inclination of the slope 62B with respect to the upper surface 12A depending on the magnitudes of the heights H1 and H2. For example, the maximum angle of inclination of the slope 62B with respect to the upper surface 12A may be larger than the maximum angle of inclination of the slope 61B with respect to the upper surface 12A. Even in such a case, the maximum angle of inclination of the slope 62B with respect to the upper surface 12A is, for example, 5 degrees to 45 degrees, preferably 5 degrees to 30 degrees, more preferably 10 degrees to 20 degrees.

A plurality of protrusions 70 are formed on the upper surface 13A of the movable portion 13. The protrusions 70 correspond to examples of first protrusions of the movable portion 13. The plurality of protrusions 70 include a protrusion 71 and a protrusion 72, which are different in height from each other. The protrusion 71 corresponds to an example of a low-height protrusion, and the protrusion 72 corresponds to an example of a high-height protrusion having a larger dimension in the Z-axis direction than the protrusion 71. The protrusion 72 is closer to the support portion 16 than the protrusion 71. The protrusion 71 has the same structure as the protrusion 61, and the protrusion 72 has the same structure as the protrusion 62. Accordingly, the description of the structures of the protrusions 71 and 72 is omitted.

The planar shape of the protrusions 60 and 70 may be circular as illustrated in FIG. 4 or rod-shaped as illustrated in FIG. 5. In the case where the protrusions 60 and 70 are rod-shaped, the protrusions 60 and 70 can diffuse the impact upon a collision with the upper cover 30, thereby preventing or reducing damage resulting from stress concentration.

The number of protrusions formed on each of the upper surfaces 12A and 13A of the movable portions 12 and 13 may be at least one. In other words, the number of protrusions formed on each of the upper surfaces 12A and 13A of the movable portions 12 and 13 may be one, or may be three or more. The number of protrusions formed on the movable portion 12 may be different from the number of protrusions formed on the movable portion 13. In the case where a plurality of protrusions are formed on the movable portion 12, the height of some or all of the protrusions may be the same.

The spring portion 14 connects the movable portion 12 and the support portion 16 to each other, and holds the movable portion 12 so that the movable portion 12 can move up and down. The spring portion 15 connects the movable portion 13 and the support portion 16 to each other, and holds the movable portion 13 so that the movable portion 13 can move up and down. The spring portions 14 and 15 are configured to be elastically deformable by forming a plurality of slits passing through the silicon substrate F10 in the Z-axis direction.

The support portion 16 supports the movable portions 12 and 13 and serves as a starting point of the movement of the movable portions 12 and 13. The support portion 16 is bonded to a securing portion 24 of the lower cover 20. In other words, the support portion 16 is connected to the lower cover 20. However, the support portion 16 is not necessarily connected to the lower cover 20 as long as the support portion 16 can support the movable portions 12 and 13. For example, the support portion 16 may be connected to the upper cover 30 or may be connected to both the lower cover 20 and the upper cover 30. The support portion 16 may be connected to the peripheral portion 17 of the device layer 10.

The peripheral portion 17 is provided around the movable portions 12 and 13 in the XY plane direction. The peripheral portion 17 is spaced apart from the movable portions 12 and 13 in the XY plane direction. The peripheral portion 17 has a frame shape surrounding the movable space 11 in the XY plane direction. The movable portions 12 and 13 and the peripheral portion 17 form a recess on the upper cover 30 side of the device layer 10.

Referring to FIG. 2, the peripheral portion 17 has an upper surface 17A, a lower surface 17B, and a peripheral slope 17C. The upper surface 17A corresponds to an example of the bonding surface bonded to the upper cover 30, and the lower surface 17B corresponds to an example of the bonding surface bonded the lower cover 20. The peripheral slope 17C is provided between the upper surface 17A and the movable portions 12 and 13 and corresponds to part of the inner surface of the frame-shaped peripheral portion 17. The peripheral slope 17C has a curved surface and forms, for example, a downwardly convex shape.

The peripheral slope 17C has a height H0 in the Z-axis direction. The height H0 is the maximum distance in the Z-axis direction from the upper surface 12A to the upper surface 17A. The dimension of the peripheral slope 17C in the direction intersecting the upper surface 12A is larger than the dimensions of the protrusions 61 and 62 in the direction intersecting the upper surface 12A. In other words, the relationship H1<H2<H0 holds. The maximum angle of inclination of the peripheral slope 17C with respect to the upper surface 12A may be substantially the same as at least one of the maximum angle of inclination of the slope 61B with respect to the upper surface 12A and the maximum angle of inclination of the slope 62B with respect to the upper surface 12A. The maximum angle of inclination of the peripheral slope 17C with respect to the upper surface 12A, the maximum angle of inclination of the slope 61B with respect to the upper surface 12A, and the maximum angle of inclination of the slope 62B with respect to the upper surface 12A may differ depending on the magnitudes of the heights H0, H1, and H2. For example, the maximum angle of inclination of the peripheral slope 17C with respect to the upper surface 12A may be larger than the maximum angle of inclination of the slope 62B with respect to the upper surface 12A and the maximum angle of inclination of the slope 61B with respect to the upper surface 12A. Even in such a case, the maximum angle of inclination of the peripheral slope 17C with respect to the upper surface 12A is, for example, 5 degrees to 45 degrees, preferably 5 degrees to 30 degrees, more preferably 10 degrees to 20 degrees. The maximum angle of inclination of the peripheral slope 17C with respect to the upper surface 12A is, for example, the angle of inclination of the peripheral slope 17C with respect to the upper surface 12A at the midpoint between the upper surface 12A and the upper surface 17A in the Z-axis direction. In other words, the maximum angle of inclination of the peripheral slope 17C with respect to the upper surface 12A is the angle of inclination of the peripheral slope 17C with respect to the upper surface 12A at a height of H0/2 from the upper surface 12A.

The lower cover 20 is formed by a silicon substrate P10 and a silicon oxide film P11. The silicon oxide film P11 is disposed on an upper surface of the lower cover 20 that is bonded to the device layer 10. The silicon substrate P10 of the lower cover 20 is bonded to the silicon substrate F10 of the device layer 10 with the silicon oxide film P11 interposed therebetween.

The lower cover 20 has a bottom plate 22, a side wall 23, and the securing portion 24. The bottom plate 22 is spaced apart from the movable portions 12 and 13 in the thickness direction. The bottom plate 22 is a plate-like portion having a main surface extending along the XY plane. The bottom plate 22 is formed by the silicon substrate P10. The side wall 23 extends from the peripheral portion of the bottom plate 22 toward the upper cover 30. The side wall 23 is a frame-like portion surrounding the movable portions 12 and 13 in plan view. A base end portion of the side wall 23 that is connected to the bottom plate 22 is formed by the silicon substrate P10. The silicon oxide film P11 is disposed on a tip end portion of the side wall 23, and the side wall 23 is bonded to the peripheral portion 17 of the device layer 10 with the silicon oxide film P11 interposed therebetween. A movable space 21 surrounded by the bottom plate 22 and the side wall 23 is formed on the side of the lower cover 20 facing the movable portions 12 and 13 of the device layer 10. The movable space 21 is a rectangular parallelepiped-shaped opening that opens toward the movable portions 12 and 13. The securing portion 24 extends from the bottom plate 22 toward the support portion 16 of the device layer 10. A base end portion of the securing portion 24 that is connected to the bottom plate 22 is formed by the silicon substrate P10. The silicon oxide film P11 is disposed on a tip end portion of the securing portion 24, and the securing portion 24 is bonded to the support portion 16 with the silicon oxide film P11 interposed therebetween. The securing portion 24 secures the support portion 16.

The upper cover 30 has a flat plate shape. The upper cover 30 is formed, for example, by silicon substrates Q10 and a glass substrate Q11. The silicon substrates Q10 are composed of, for example, a p-type silicon (Si) semiconductor. The silicon (Si) used for the silicon substrates Q10 has, for example, a resistance of about 10 mΩ·cm. The glass substrate Q11 is composed of glass containing silicon oxide (e.g., SiO₂) as a main component. The main component in glass refers to a component that accounts for 50 mass % or more of the total composition of the glass. In an example, the glass substrate Q11 is composed of silicate glass containing SiO₂ as a main component. The silicon substrates Q10 are disposed in a plurality of regions spaced from each other in the XY plane direction. The glass substrate Q11 electrically insulates, from each other, the plurality of silicon substrates Q10 disposed in the regions spaced from each other in the XY plane direction.

The electrodes E1 and E2 are disposed on the lower surface of the upper cover 30. The electrode E1 forms an electrostatic capacity between the electrode E1 and the movable portion 12, and the electrode E2 forms an electrostatic capacity between the electrode E2 and the movable portion 13. The electrode E1 faces the movable portion 12 in the Z-axis direction, and the electrode E2 faces the movable portion 13 in the Z-axis direction. The electrodes E1 and E2 are provided across the silicon substrates Q10 and the glass substrate Q11. The electrodes E1 and E2 are composed of, for example, aluminum (Al), an aluminum-copper alloy (AlCu), titanium (Ti), or a titanium-tungsten alloy (TiW).

The electrode E1 has openings in regions facing the protrusions 60. The openings in the electrode E1 expose the glass substrate Q11 to the protrusions 60. The electrode E2 has openings in regions facing the protrusions 70. The openings in the electrode E2 expose the glass substrate Q11 to the protrusions 70. Even if the movable portions 12 and 13 are significantly displaced upward, the protrusions 60 and 70 make contact with the glass substrate Q11 but not with the silicon substrates Q10 or the electrodes E1 and E2. Therefore, in this case, the movable portion 12 and the electrode E1 are unlikely to be electrically short-circuited, and the movable portion 13 and the electrode E2 are unlikely to be electrically short-circuited. The fracture stress (7.8 GPa) of SiO₂, which is a main component of the glass substrate Q11, is higher than the fracture stress (4.4 GPa) of Si, which is a main component of the silicon substrates Q10. Therefore, the glass substrate Q11 is more resistant to external impact than the silicon substrates Q10. Exposing the glass substrate Q11 instead of the silicon substrates Q10 from the openings in the electrodes E and E2 prevents or reduces damage to the upper cover 30 when the protrusions 60 and 70 collide with the upper cover 30.

Terminals T1, T2, and T3 are disposed on the upper surface of the upper cover 30. The terminal T1 is electrically coupled to the electrode E1 by the silicon substrate Q10. The terminal T2 is electrically coupled to the electrode E2 by the silicon substrate Q10. The terminal T3 is electrically coupled to the movable portions 12 and 13 by the silicon substrate Q10. The terminals T1, T2, and T3 are electrically insulated from each other by the glass substrate Q11. The terminals T1, T2, and T3 are composed of, for example, aluminum (Al), an aluminum-copper alloy (AlCu), titanium (Ti), or a titanium-tungsten alloy (TiW).

The materials of the upper cover 30 are not limited to the silicon substrates Q10 and the glass substrate Q11. The upper cover 30 may have a silicon oxide film instead of the glass substrate Q11, or may further have a silicon oxide film in addition to the silicon substrates Q10 and the glass substrate Q11. The upper cover 30 may be formed by using a compound semiconductor substrate, a glass substrate, a ceramic substrate, a resin substrate, or a combination of these substrates. Through-electrodes penetrating the upper cover 30 in the Z-axis direction may be further provided to establish electrical coupling between the terminal T1 and the electrode E1 and electrical coupling between the terminal T2 and the electrode E2. Such a through-electrode is formed, for example, by filling a through-hole with polycrystalline silicon (Poly-Si), copper (Cu), gold (Au), or other materials.

When the device layer 10 and the lower cover 20 are regarded as the MEMS substrate 50, for example, the silicon substrate P10 of the lower cover 20 corresponds to the support substrate (handle layer) of an SOI substrate, the silicon oxide film P11 of the lower cover 20 corresponds to the BOX layer of the SOI substrate, and the silicon substrate F10 of the device layer 10 corresponds to the active layer (device layer) of the SOI substrate.

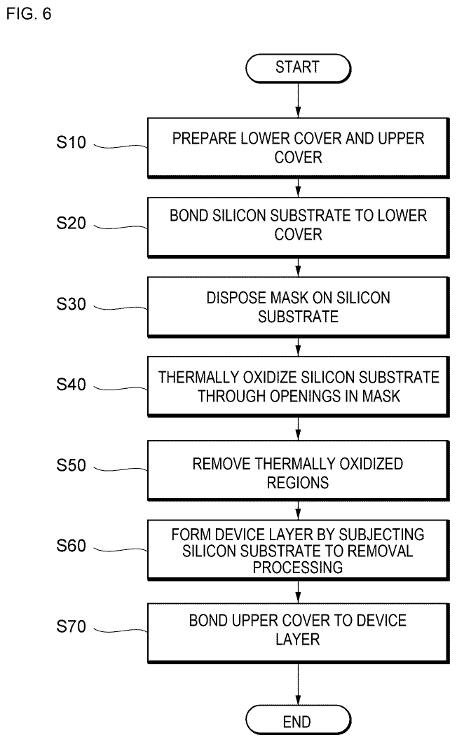

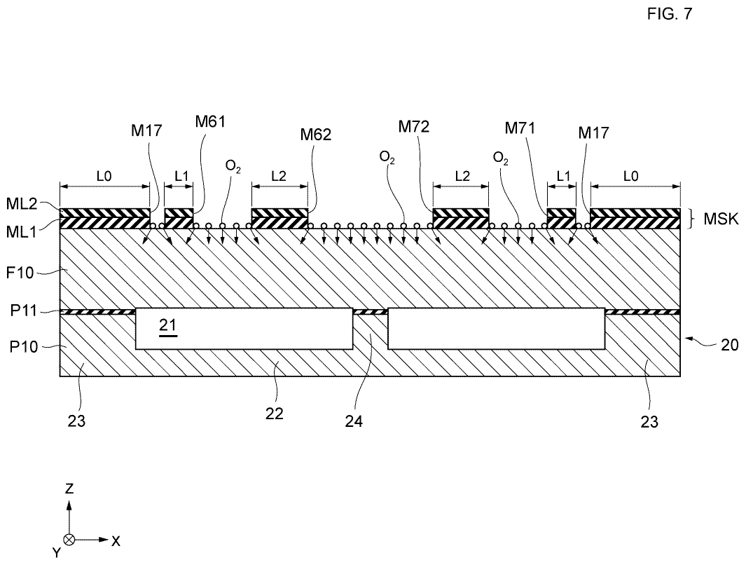

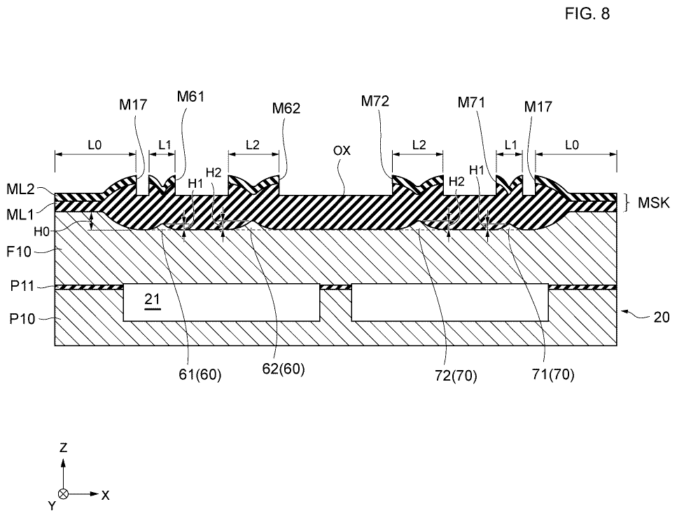

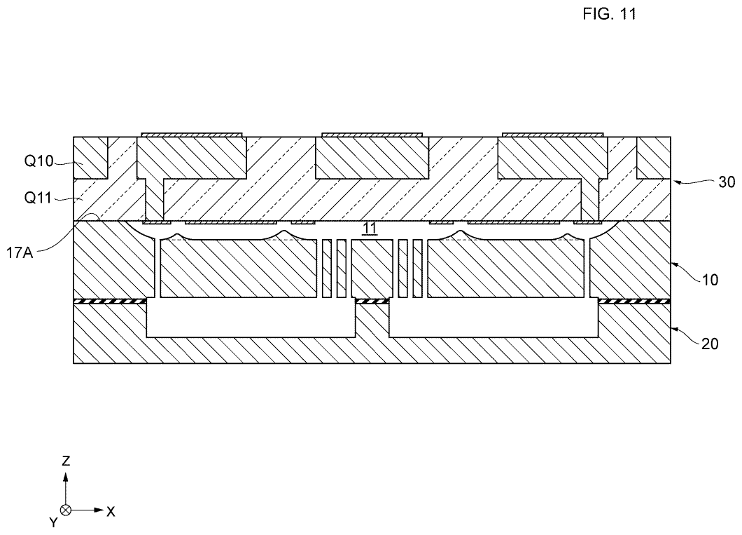

Next, the method for manufacturing the capacitive sensor 1 according to the first embodiment will be described with reference to FIGS. 6 to 11. FIG. 6 is a flow chart of the method for manufacturing the capacitive sensor according to the embodiment. FIG. 7 is a cross-sectional view illustrating the process for manufacturing the capacitive sensor. FIGS. 8 to 11 are cross-sectional views illustrating the process for manufacturing the capacitive sensor.

First, the lower cover 20 and the upper cover 30 are prepared (S10).

Specifically, first, the silicon substrate P10 is prepared and subjected to single-sided mirror polishing. The silicon oxide film P11 is formed on the mirror surface side of the silicon substrate P10. The silicon oxide film P11 and the upper surface side of the silicon substrate P10 are removed by dry etching or other methods to form the movable space 21. A composite substrate composed of the silicon substrates Q10 and the glass substrate Q11 is prepared and subjected to single-sided mirror polishing. The electrodes E1 and E2 are formed on the mirror surface side of the composite substrate.

Next, the silicon substrate F10 is bonded to the lower cover 20 (S20).

Specifically, first, the silicon substrate F10 is prepared and subjected to double-sided mirror polishing. One mirror surface of the silicon substrate F10 and the silicon oxide film P11 are brought into contact with each other and heat-treated so that the silicon substrate F10 and the silicon oxide film P11 are directly bonded together.

Next, a mask MSK is disposed on the silicon substrate F10 (S30).

Specifically, first, a silicon oxide film ML1 is disposed on the silicon substrate F10. Next, a silicon nitride film ML2 is disposed on the silicon oxide film ML1. The mask MKS has the silicon oxide film ML1 and the silicon nitride film ML2. The silicon nitride film ML2 has lower oxygen permeability than the silicon oxide film ML1, and the silicon oxide film ML1 has lower thermal stress than the silicon nitride film ML2. The silicon nitride film ML2 inhibits the penetration of oxygen into the silicon substrate F10, and the silicon oxide film ML1 prevents or reduces damage to the silicon substrate F10 caused by the thermal stress of the silicon nitride film ML2.

Next, the silicon oxide film ML1 and the silicon nitride film ML2 are patterned to form openings in the mask MKS. An opening is formed around a part of the mask MSK that is located at the position where the protrusion 61 is to be formed, thereby providing a mask M61 surrounded by the opening. An opening is formed around a part of the mask MSK that is located at the position where the protrusion 62 is to be formed, thereby providing a mask M62 surrounded by the opening. An opening is formed around a part of the mask MSK that is located at the position where the protrusion 71 is to be formed, thereby providing a mask M71 surrounded by the opening. An opening is formed around a part of the mask MSK that is located at the position where the protrusion 72 is to be formed, thereby providing a mask M72 surrounded by the opening. An opening is formed on the inner side of the outer edge portion of the mask MSK, thereby providing a mask M17 surrounding the opening. In other words, the mask MSK has the masks M17, M61, M62, M71, and M72. The masks M61, M62, M71, and M72 correspond to examples of a plurality of first masks for forming protrusions. The masks M61 and M71 correspond to examples of masks having a first area and used for forming low-height protrusions. The masks M62 and M72 correspond to examples of masks having a second area larger than the first area and used for forming high-height protrusions. The mask M17 corresponds to an example of a second mask for forming the peripheral portion.

A mask having a small area is provided at the position where a low-height protrusion is to be formed, and a mask having a large area is provided at the position where a high-height protrusion is to be formed. A mask having a larger area than the masks at the positions where the protrusions are to be formed is provided at the position where the peripheral portion is to be formed. In the example illustrated in FIG. 7, the length L1 of the masks M61 and M71 in the X-axis direction is larger than the length L2 of the masks M62 and M72 in the X-axis direction. The length L0 of the mask M17 in the X-axis direction is larger than the length L2. In other words, the relationship L1<L2<L0 holds.

The mask MSK is not limited to the multilayer film composed of two layers: the silicon oxide film ML1 and the silicon nitride film ML2 described above. For example, the mask MSK may be a single-layer film composed of a silicon nitride film, or may be a multilayer film composed of three or more layers including the silicon oxide film and the silicon nitride film. The mask MSK may be a single-layer film or a multilayer film other than the silicon oxide film and the silicon nitride film.

Next, the silicon substrate F10 is thermally oxidized through the openings in the mask MSK (S40).

Specifically, the surface of the silicon substrate F10 on which the mask MSK is disposed is heated in an oxygen atmosphere. Referring to FIG. 8, oxygen penetrates the silicon substrate F10 from the openings in the mask MSK and oxidizes silicon to form thermally oxidized regions OX. The thermally oxidized regions OX expand from the openings. The thermally oxidized regions OX are connected to each other under the masks M61, M62, M71, and M72 for forming protrusions, and the silicon substrate F10 confined by the thermally oxidized regions OX (hereinafter referred to as “oxidation confinement”) forms the protrusions 61, 62, 71, and 72.

Since the length L2 of the masks M62 and M72 is larger than the length L1 of the masks M61 and M71, the depth of the connected areas in which the thermally oxidized regions OX are connected to each other under the masks M62 and M72 is smaller than the depth of the connected areas in which the thermally oxidized regions OX are connected to each other under the masks M61 and M71. Therefore, the height H2 of the protrusions 62 and 72 formed by oxidation confinement under the masks M62 and M72 is larger than the height H1 of the protrusions 61 and 71 formed by oxidation confinement under the mask M61 and M71.

The length L0 of the mask M17 is larger than the distance that the thermally oxidized region OX penetrates. Therefore, on the upper surface of the silicon substrate F10 in contact with the mask M17, the thermally oxidized region OX is located in an area adjacent to the opening, and the silicon semiconductor remains in an area away from the opening.

Next, the thermally oxidized regions OX are removed (S50).

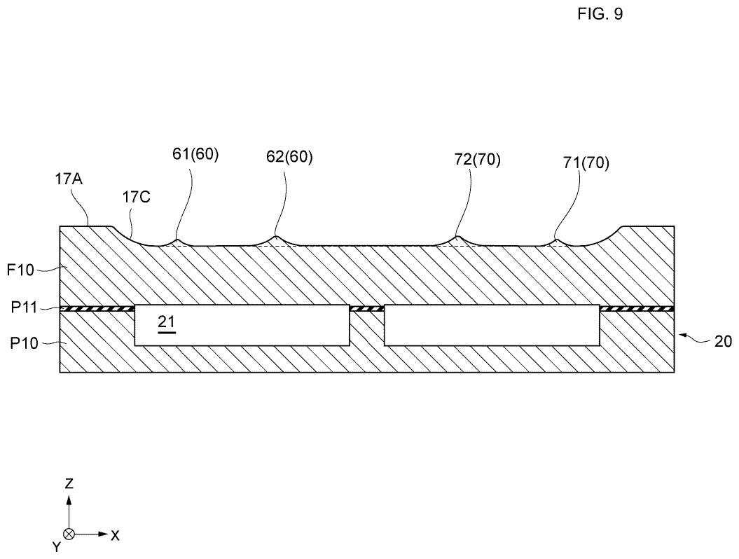

Specifically, reference to FIG. 9, the thermally oxidized regions Ox, the silicon oxide film ML1, and the silicon nitride film ML2 are removed to expose the upper surface of the silicon substrate F10. With the removal of the thermally oxidized regions OX, the protrusions 61, 62, 71, and 72 are formed at the positions where the thermally oxidized regions OX are connected to each other under the masks M61, M62, M71, and M72 for forming protrusions. Under the mask M17 for forming the peripheral portion, the peripheral slope 17C of the peripheral portion 17 is formed in the region where the thermally oxidized region OX has penetrated, and the upper surface 17A of the peripheral portion 17 is formed in the region where the thermally oxidized region OX has not penetrated.

Next, the device layer 10 is formed by subjecting the silicon substrate F10 to removal processing (S60).

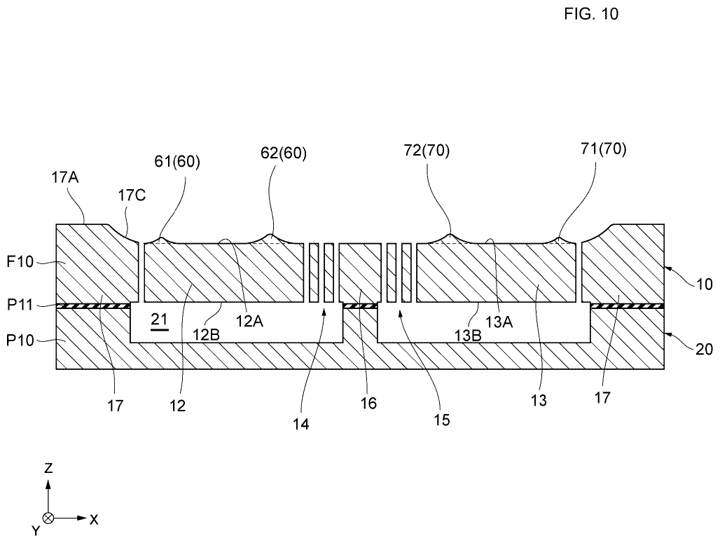

Specifically, a photoresist is patterned on the upper surface of the silicon substrate F10, and the silicon substrate F10 is subjected to removal processing by dry etching. This process forms the movable portions 12 and 13, the spring portions 14 and 15, the support portion 16, and the peripheral portion 17, as illustrated in FIG. 10. When the photoresist is provided on the upper surface of the silicon substrate F10, the photoresist is applied, for example, by spin coating. Since the height of the protrusions 60 does not change discontinuously and the protrusions 60 have gentle slopes, the protrusions 60 do not hinder the spreading of the resist, that is, the protrusions 60 are unlikely to cause uneven application of the resist.

Next, the upper cover 30 is bonded to the device layer 10 (S70).

Specifically, the upper surface 17A of the peripheral portion 17 of the device layer 10 is brought into contact with the glass substrate Q11 of the upper cover 30, and the silicon substrate F10 and the glass substrate Q11 are bonded to each other by anodic bonding or direct bonding. This process seals the gap between the upper cover 30 and the device layer 10 having the peripheral slope 17C as the inner surface to form the movable space 11.

Finally, the terminals T1, T2, and T3 are formed on the upper surface side of the glass substrate Q11.

As described above, the capacitive sensor 1 has the upper cover 30 and the device layer 10 having the movable portion 12 configured such that a change in electrostatic capacity is detected based on the distance between the upper cover 30 and the movable portion 12. The protrusions 61 and 62 are formed on the upper surface 12A of the movable portion 12. The protrusions 61 and 62 respectively have the top portions 61A and 62A having curved surfaces in central areas of the protrusions 61 and 62 and the slopes 61B and 62B around the top portions 61A and 62A.

According to this configuration, the protrusions 61 and 62 can reduce the occurrence of so-called sticking, an operational defect in which the movable portion 12 adheres to the upper cover 30. Since the top portions 61A and 62A of the protrusions 61 and 62, which will make contact with the upper cover 30, have curved surfaces, the impact generated upon a collision of the protrusions 61 and 62 with the upper cover 30 can be dispersed compared to protrusions having edges at the positions where the protrusions make contact with the upper cover 30. In other words, this configuration prevents or reduces damage to the protrusions 61 and 62 and the upper cover 30. Therefore, the performance deterioration and other reliability degradation caused by dust generation inside the capacitive sensor 1 can be prevented or reduced.

In one aspect of the foregoing, the slopes 61B and 62B of the protrusions 61 and 62 have curved surfaces, and W1/2 and W2/2 corresponding to the dimensions of the slopes 61B and 62B in the X-axis direction are larger than H1 and H2, which are the dimensions of the slopes 61B and 62B in the Z-axis direction. In other words, the relationships 1<(W1/2)/H1 and 1<(W2/2)/H2 hold.

According to this aspect, the protrusions 61 and 62 are less likely to inhibit the spreading of the photoresist during application of the photoresist to the surface having the protrusions 61 and 62 thereon. To prevent or reduce the inhibition of spreading of the photoresist, the relationships 2≤(W1/2)/H1 and 2≤(W2/2)/H2 more preferably hold, and the relationships 4≤(W1/2)/H1 and 4≤(W2/2)/H2 even more preferably hold. In order for the protrusions 61 and 62 to fully demonstrate their function of preventing sticking, for example, the relationships (W1/2)/H1≤20 and (W2/2)/H2≤20 preferably hold, the relationships (W1/2)/H1≤10 and (W2/2)/H2≤10 more preferably hold, and the relationships (W1/2)/H1≤7.5 and (W2/2)/H2≤7.5 even more preferably hold.

In one aspect, the maximum angle of inclination of the slopes 61B and 62B with respect to the upper surface 12A is 5 degrees to 45 degrees, preferably 5 degrees to 30 degrees.

According to this aspect, the protrusions 61 and 62 can fully perform their function of preventing sticking when the maximum angle of inclination is 5 degrees or more. The protrusions 61 and 62 are less likely to inhibit the spreading of the photoresist during application of the photoresist to the surface having the protrusions 61 and 62 thereon when the maximum angle of inclination is 45 degrees or less, preferably 30 degrees or less. It is noted that the protrusions 61 and 62 can enhance their function of preventing sticking when the maximum angle of inclination is 10 degrees or more. The protrusions 61 and 62 are even less likely to inhibit the spreading of the photoresist when the maximum angle of inclination is 20 degrees or less.

In one aspect of the foregoing, the plurality of protrusions 60 include the protrusions 61 and 62, which are different in height from each other.

According to this aspect, the height of the protrusions can be designed in accordance with the movable range of the movable portion 12.

In one aspect of the foregoing, the high-height protrusion 62 having the height H2, among the protrusions 61 and 62, is closer to the support portion 16 than the low-height protrusion 61 having the height H1.

According to this aspect, the movable portion 12 is configured to be movable with respect to the support portion 16 serving as a starting point, and the high-height protrusion 62 is formed in an area near the support portion 16, which is close to the starting point and where the movable range is narrow, and the low-height protrusion 61 is formed in an area near the peripheral portion 17, which is away from the starting point and where the movable range is wide. This configuration allows the impact to be dispersed between the protrusion 61 and the protrusion 62 upon a collision of the movable portion 12 with the upper cover 30.

In one aspect of the foregoing, the electrode E1 of the upper cover 30, which forms an electrostatic capacity with the movable portion 12, has openings in the regions facing the protrusions 61 and 62.

According to this aspect, electrical short circuiting between the movable portion 12 and the electrode E1 can be prevented when the movable portion 12 collides with the upper cover 30.

As described above, the protrusions 61 and 62 are formed by oxidation confinement of the silicon substrate F10 by the thermally oxidized regions OX using the masks M61 and M62.

According to this process, the protrusions 61 and 62 having smooth curved surfaces from the upper surface 12A to the top portions 61A and 62A can be formed. The protrusions 61 and 62 have gently sloping hill-like shapes having the widths W1 and W2 sufficiently larger than the heights H1 and H2. Therefore, the protrusions 61 and 62 are less likely to inhibit the spreading of the photoresist during application of the photoresist to the surface having the protrusions 61 and 62 thereon.

In one aspect of the foregoing, the peripheral slope 17C of the peripheral portion 17 can be formed simultaneously with the protrusions 61 and 62 by removing the thermally oxidized regions OX.

According to this aspect, the peripheral slope 17C for forming the movable space 11 and the protrusions 61 and 62 can be formed in the same process. Therefore, the process for manufacturing the capacitive sensor 1 can be simplified compared to a method for manufacturing the capacitive sensor that includes a step of forming the protrusions separately from a step of forming the movable space.

In one aspect of the foregoing, the mask M61 having the length L1 is provided at the position where the low-height protrusion 61 is to be formed, and the mask M62 having the length L2 is provided at the position where the high-height protrusion 62 is to be formed. The length L2 is larger than the length L1.

According to this configuration, there is a correlation between the area of the masks and the height of the protrusions, and the size and shape of the protrusions can be easily changed by changing the shape and size of the masks. In other words, the degree of freedom regarding the design of the protrusions can be improved.

In one aspect of the foregoing, the mask MSK has the silicon oxide film ML1 on the silicon substrate F10 and the silicon nitride film ML2 on the silicon oxide film ML1.

According to this configuration, oxygen permeating through the mask MSK can be efficiently inhibited from penetrating the silicon substrate F10 when the mask MSK has the silicon oxide film ML1 having lower oxygen permeability than the silicon nitride film ML2. Damage to the silicon substrate F10 caused by thermal stress of the mask MSK can be prevented or reduced when the mask MSK has the silicon nitride film ML2 having lower thermal stress than the silicon oxide film ML1.

Other embodiments will be described below. The same or similar components as those described in the first embodiment are assigned with the same or similar reference signs, and the description thereof is omitted as appropriate. The similar operational advantages obtained by similar configurations will not be described repeatedly.

### Second Embodiment

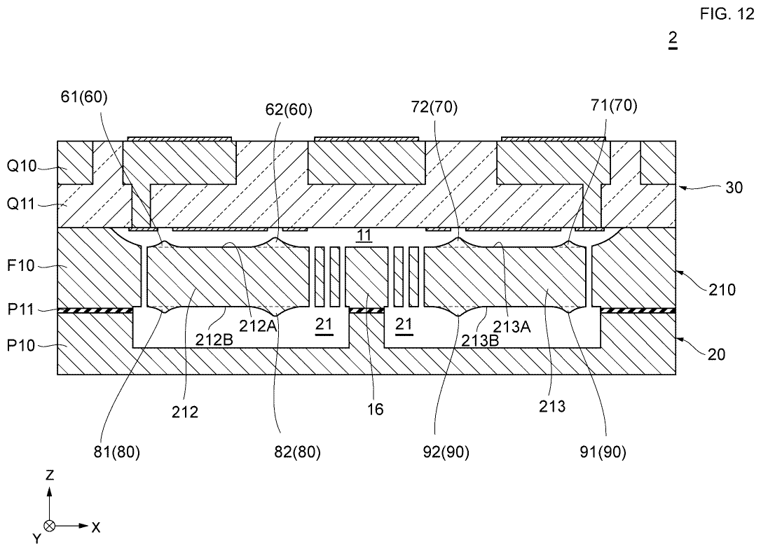

Next, the structure of a capacitive sensor 2 according to a second embodiment will be described with reference to FIG. 12. FIG. 12 is a cross-sectional view of the capacitive sensor according to the second embodiment.

A movable portion 212 of a device layer 210 also has a plurality of protrusions 80 on a lower surface 212B, and a movable portion 213 of the device layer 210 also has a plurality of protrusions 90 on a lower surface 213B. The protrusions 80 correspond to examples of second protrusions of the movable portion 212. The protrusions 90 correspond to examples of second protrusions of the movable portion 213. The plurality of protrusions 80 have a low-height protrusion 81 and a high-height protrusion 82 higher than the protrusion 81. The plurality of protrusions 90 have a low-height protrusion 91 and a high-height protrusion 92 higher than the protrusion 91. The protrusion 82 is closer to the support portion 16 than the protrusion 81, and the protrusion 92 is closer to the support portion 16 than the protrusion 91. In an example, when the upper surfaces 212A and 213A are viewed in plan view, the protrusion 81 is formed at a position overlapping the protrusion 61, the protrusion 82 is formed at a position overlapping the protrusion 62, the protrusion 91 is formed at a position overlapping the protrusion 71, and the protrusion 92 is formed at a position overlapping the protrusion 72.

According to this embodiment, the protrusions 80 can prevent or reduce sticking between the movable portion 212 and the lower cover 20. The protrusions 90 can prevent or reduce sticking between the movable portion 213 and the lower cover 20.

The number of protrusions 80 may be at least one, and the number of protrusions 90 may be at least one. In other words, the number of protrusions formed on each of the lower surfaces 212B and 213B of the movable portions 212 and 213 may be one, or may be three or more. The number of protrusions formed on the lower surface 212B of the movable portion 212 may be different from the number of protrusions formed on the lower surface 213B of the movable portion 213. The number of protrusions formed on the lower surface 212B of the movable portion 212 may be different from the number of protrusions formed on a upper surface 212A of the movable portion 212. The number of protrusions formed on the lower surface 213B of the movable portion 213 may be different from the number of protrusions formed on a upper surface 213A of the movable portion 213. In the case where a plurality of protrusions are formed on the lower surface 212B of the movable portion 212, the height of some or all of the protrusions may be the same. In the case where a plurality of protrusions are formed on the lower surface 213B of the movable portion 213, the height of some or all of the protrusions may be the same.

The embodiments according to the present disclosure can be applied to, for example, any sensor that detects changes in electrostatic capacity, such as inertial sensors such as acceleration sensors and gyro sensors, or pressure sensors, without limitation.

As described above, the capacitive sensor having improved reliability and the method for manufacturing the capacitive sensor can be provided according to the aspects of the present disclosure.

The embodiments described above are intended to facilitate understanding of the present disclosure and should not be construed as limiting the present disclosure. The present disclosure may be modified/improved without departing from the spirit of the present disclosure, and the present disclosure also includes equivalents thereof. In other words, the embodiments with design modifications appropriately made by those skilled in the art are also included within the scope of the present disclosure, as long as they retain the features of the present disclosure. For example, the elements of each embodiment, as well as their arrangement, materials, conditions, shapes, sizes, and the like, are not limited to the examples described above and may be appropriately modified. The elements of each embodiment can be combined with one another to the extent that combining them is technically possible, and any combination thereof is also included within the scope of the present disclosure, as long as it includes the features of the present disclosure.

### REFERENCE SIGNS LIST

1 capacitive sensor
10 device layer
11 movable space
12, 13 movable portion
12a, 13a upper surface
12b, 13b lower surface
14, 15 spring portion
16 support portion
17 peripheral portion
17a upper surface
17b lower surface
17c peripheral slope
20 lower cover
30 upper cover
e1, e2 electrode
t1, t2, t3 terminal
p10, q10, f10 silicon substrate
p11 silicon oxide film
q11 glass substrate
60, 61, 62, 70, 71, 72 protrusion
61a, 62a top portion
61b, 62b slope

1. A capacitive sensor comprising:
a first substrate layer; and
a device layer having a movable portion,
wherein the movable portion has a first main surface facing the first substrate layer and at least one first protrusion on the first main surface,
the at least one first protrusion has a first top portion having a curved surface in a central area of the at least one first protrusion in a plan view of the device layer, and a first slope around the first top portion, and
the capacitive sensor is configured to detect a change in electrostatic capacity based on a distance between the first substrate layer and the movable portion.

2. The capacitive sensor according to claim 1, wherein the first slope has a curved surface.

3. The capacitive sensor according to claim 1, wherein a first dimension of the first slope along the first main surface is larger than a second dimension of the first slope in a direction intersecting the first main surface.

4. The capacitive sensor according to claim 1, wherein the device layer comprises a silicon substrate, and
the first slope is in a plane different from a crystal plane of the silicon substrate.

5. The capacitive sensor according to claim 1, wherein a maximum angle of inclination of the first slope with respect to the first main surface is 5 degrees to 45 degrees.

6. The capacitive sensor according to claim 5, wherein the maximum angle of inclination of the first slope with respect to the first main surface is 5 degrees to 30 degrees.

7. The capacitive sensor according to claim 1, wherein the at least one first protrusion includes a plurality of protrusions having different heights.

8. The capacitive sensor according to claim 7, wherein the device layer further includes a support portion supporting the movable portion, and
the plurality of protrusions include:
a low-height protrusion; and
a high-height protrusion that is closer to the support portion than the low-height protrusion and has a larger dimension in a direction intersecting the first main surface than the low-height protrusion.

9. The capacitive sensor according to claim 1, wherein
the first substrate layer has an electrode on a surface facing the movable portion of the device layer, and
the electrode has an opening in a region facing the first protrusion.

10. The capacitive sensor according to claim 1, wherein
the device layer further includes a peripheral portion around the movable portion,
the movable portion and the peripheral portion define a recess on a first substrate layer side of the device layer,
the peripheral portion has a bonding surface bonded to the first substrate layer and a peripheral slope between the bonding surface and the movable portion, and
a dimension of the peripheral slope in a direction intersecting the first main surface is larger than a dimension of the at least one first protrusion in the direction intersecting the first main surface.

11. The capacitive sensor according to claim 10, wherein a maximum angle of inclination of the peripheral slope with respect to the first main surface is 5 degrees to 45 degrees.

12. The capacitive sensor according to claim 11, wherein the maximum angle of inclination of the peripheral slope with respect to the first main surface is 5 degrees to 30 degrees.

13. The capacitive sensor according to claim 1, wherein the device layer further includes a peripheral portion around the movable portion,
the capacitive sensor further comprising:
a second substrate layer bonded to the peripheral portion of the device layer and facing the first substrate layer with the device layer interposed therebetween.

14. The capacitive sensor according to claim 13, wherein
the device layer further includes a support portion supporting the movable portion, and
the support portion of the device layer is bonded to the second substrate layer.

15. The capacitive sensor according to claim 13, wherein
the movable portion has at least one second protrusion on a second main surface facing the second substrate layer, and
the second protrusion has a second top portion having a curved surface and a second slope around the second top portion.

16. The capacitive sensor according to claim 15, wherein the at least one second protrusion is located at a position overlapping the at least one first protrusion.

17. A method for manufacturing a capacitive sensor, the method comprising:
disposing a first mask on a surface of a base;
thermally oxidizing the base through openings in the first mask to form thermally oxidized regions and connecting the thermally oxidized regions expanding from the openings to each other under the first mask;
removing the thermally oxidized regions from the base so as to form a protrusion at a position where the thermally oxidized regions are connected to each other; and
forming a movable portion by subjecting the base to removal processing.

18. The method for manufacturing a capacitive sensor according to claim 17, the method further comprising:
disposing a second mask on the surface of the base,
wherein the thermal oxidization of the base further includes expanding the thermally oxidized regions from the openings to under the second mask while leaving the base in contact with the second mask, and
the removal of the thermally oxidized regions further includes forming a bonding surface in a peripheral portion at a position where the second mask is in contact with the base, and forming a peripheral slope of the peripheral portion at a position where the thermally oxidized regions expand from the openings to under the second mask.

19. The method for manufacturing a capacitive sensor according to claim 17, wherein the disposing of the first mask includes disposing a plurality of masks having different areas,
the method further comprising forming:
a low-height protrusion using a low-height mask having a first area and a high-height protrusion using a high-height mask having a second area larger than the first area, among the plurality of masks.

20. The method for manufacturing a capacitive sensor according to claim 17, wherein the disposing of the first mask includes:
disposing a silicon oxide film on the base, and wherein the base comprises a silicon substrate, and
disposing a silicon nitride film on the silicon oxide film.
